(19) United States
(12) Patent Application Publication
(10) Pub. No.: US 2009/0298697 A1
(43) Pub. Date: Dec. 3, 2009

(54) MULTIFILAMENTARY SUPERCONDUCTING ARTICLES AND METHODS OF FORMING THEREOF

(75) Inventors: Xun Zhang, Schenectady, NY (US); Drew W. Hazelton, Selkirk, NY (US); Venkat Selvamanickam, Wynantskill, NY (US)

Correspondence Address: LARSON NEWMAN & ABEL, LLP, 5914 WEST COURTYARD DRIVE, SUITE 200, AUSTIN, TX, 78730, US

(73) Assignee: SUPERPOWER, INC., Schenectady, NY (US)

(21) Appl. No.: 12/128,376

(22) Filed: May 28, 2008

(51) Int. Cl. H01L 39/14; H01L 39/24; H01B 12/00

(52) U.S. Cl. 505/231; 505/431; 174/125.1

(57) ABSTRACT

A superconducting article is provided that includes a multifilamentary superconducting tape segment having a substrate tape, a buffer layer overlying the substrate, and filaments comprising a high temperature superconducting (HTS) material overlying the buffer layer. The filaments extend along a length of the substrate and are laterally spaced apart from an adjacent filament by a space. The multifilamentary superconducting tape segment comprises a critical current retention ratio is at least about 0.4.

### CROSS-REFERENCE TO RELATED APPLICATION(S)

### BACKGROUND

1. Field of the Disclosure

The present disclosure is directed to multifilamentary superconducting articles, and is particularly directed to low AC loss multifilamentary superconducting articles.

2. Description of the Related Art

Superconductor materials have long been known and understood by the technical community. Low-temperature superconductors (low-T_{c} or LTS) exhibiting superconducting properties at temperatures requiring use of liquid helium (4.2 K), have been known since 1911. However, it was not until somewhat recently that oxide-based high-temperature (high-T_{c}) superconductors have been discovered. Around 1986, a first high-temperature superconductor (HTS), having superconducting properties at a temperature above that of liquid nitrogen (77 K) was discovered, namely YBa₂Cu₃O₇₋ₓ (YBCO), followed by development of additional materials over the past 15 years including Bi₂Sr₂Ca₂Cu₃O_{10+y} (BSCCO), and others. The development of high-T_{c} superconductors has created the potential of economically feasible development of superconductor components and other devices incorporating such materials, due partly to the cost of operating such superconductors with liquid nitrogen rather than the comparatively more expensive cryogenic infrastructure based on liquid helium.

Of the myriad of potential applications, the industry has sought to develop use of such materials in the power industry, including applications for power generation, transmission, distribution, and storage. In this regard, it is estimated that the inherent resistance of copper-based commercial power components is responsible for billions of dollars per year in losses of electricity, and accordingly, the power industry stands to gain based upon utilization of high-temperature superconductors in power components such as transmission and distribution power cables, generators, transformers, and fault current interrupters/limiters. In addition, other benefits of high-temperature superconductors in the power industry include a factor of 3-10 increase of power-handling capacity, significant reduction in the size (i.e., footprint) and weight of electric power equipment, reduced environmental impact, greater safety, and increased capacity over conventional technology. While such potential benefits of high-temperature superconductors remain quite compelling, numerous technical challenges continue to exist in the production and commercialization of high-temperature superconductors on a large scale.

Among the challenges associated with the commercialization of high-temperature superconductors, many exist around the fabrication of a superconducting tape segment that can be utilized for formation of various power components. A first generation of superconducting tape segment includes use of the above-mentioned BSCCO high-temperature superconductor. This material is generally provided in the form of discrete filaments, which are embedded in a matrix of noble metal, typically silver. Although such conductors may be made in extended lengths needed for implementation into the power industry (such as on the order of a kilometer), due to materials and manufacturing costs, such tapes do not represent a widespread commercially feasible product.

Accordingly, a great deal of interest has been generated in the so-called second-generation HTS tapes that have superior commercial viability. These tapes typically rely on a layered structure, generally including a flexible substrate that provides mechanical support, at least one buffer layer overlying the substrate, the buffer layer optionally containing multiple films, an HTS layer overlying the buffer film, and an optional capping layer overlying the superconductor layer, and/or an optional electrical stabilizer layer overlying the capping layer or around the entire structure. However, to date, numerous engineering and manufacturing challenges remain prior to full commercialization of such second generation-tapes and devices incorporating such tapes.

With the advent of a new technology comes new problems, and in the realm of HTS tapes, reducing the alternating current (AC) losses and while maintaining the current carrying capacity is particularly troublesome. AC losses reduce the effectiveness of the conductor and are caused by magnetic fields that are generated by running a current through the superconducting article. While some superconductor designs have been suggested to mitigate the AC losses, the formation and utilization of these articles poses unique obstacles given the complex multilayered structure of second generation HTS tapes. In particular, the formation of such structures into commercially viable, long-length conductors remains a major obstacle given than such articles are expected have the capacity to handle the increasing power demands with enhanced performance and durability.

### SUMMARY

According to one aspect, a superconducting article comprising a multifilamentary superconducting tape segment is disclosed that includes a substrate tape, a buffer layer overlying the substrate, and filaments comprising a high temperature superconducting (HTS) material overlying the buffer layer. The filaments extend along a length of the substrate, laterally spaced apart from an adjacent filament by a space, and longitudinally spaced apart by a gap. The multifilamentary superconducting tape segment has a lateral inter-filament misalignment of not greater than about 100 microns.

According to another aspect, a superconducting article is disclosed that includes multifilamentary superconducting tape segment having a substrate tape, a buffer layer overlying the substrate, and filaments comprising a high temperature superconducting (HTS) material overlying the buffer layer. The filaments extend along a length of the substrate and are laterally spaced apart from adjacent filaments by a space. Also, the multifilamentary superconducting tape segment comprises a critical current retention ratio of at least about 0.6.

According to a third aspect, a method of forming a multifilamentary superconducting tape is provided that includes translating a superconducting tape on a reel-to-reel process, wherein the superconducting tape includes a substrate, a buffer layer overlying the substrate, and a HTS layer overlying the buffer layer. The method further includes forming a mask overlying the superconducting tape, and removing portions of the mask and portions of the HTS layer using abrasive particles to form a multifilamentary superconducting tape having filaments comprising the HTS material and extending along a length of the superconducting tape and laterally spaced apart from adjacent filaments by spaces.

### BRIEF DESCRIPTION OF THE DRAWINGS

The present disclosure may be better understood, and its numerous features and advantages made apparent to those skilled in the art by referencing the accompanying drawings.

FIG. 1A illustrates a prospective view showing the generalized structure of a superconducting article according to an embodiment.

FIG. 1B illustrates a prospective view showing the generalized structure of a multifilamentary superconducting article according to an embodiment.

FIG. 2 includes a plan view of a portion of a multifilamentary superconducting article according to an embodiment.

FIG. 3. includes a top view of a portion of a multifilamentary superconducting article according to an embodiment.

FIG. 4 includes a flow chart illustrating a process for forming a multifilamentary superconducting article according to an embodiment.

FIG. 5 includes a flow chart illustrating a process for forming a multifilamentary superconducting article according to an embodiment.

FIG. 6 includes a flow chart illustrating a process for forming a multifilamentary superconducting article according to an embodiment.

FIG. 7 includes a prospective view of a substrate holder for use in forming a multifilamentary superconducting article according to an embodiment.

FIG. 8 includes a substrate holder and a reticle for use in forming a multifilamentary superconducting article according to an embodiment.

FIG. 9 includes a reticle having registration marks and a superconducting tape segment having registration marks for use in forming a multifilamentary superconducting article according to an embodiment.

FIG. 10 includes a series of illustrations providing pictorial representations of a process of forming a multifilamentary superconducting article in a reel-to-reel process according to an embodiment.

FIG. 11 includes a fault current limiter (FCL) article including multifilamentary superconducting article according to an embodiment.

FIG. 12 includes a cross-sectional view of a portion of a multifilamentary superconducting article having an alternative structure according to an embodiment.

FIG. 13 includes a plot of power versus magnetic field illustrating the AC loss reduction of multifilamentary superconducting articles according to an embodiment.

FIG. 14 illustrates a graph of current versus time for a conventional FCL device during a fault state.

FIG. 15 illustrates a graph of current versus time for a FCL device incorporating a multifilamentary superconducting article according to an embodiment.

FIG. 16 illustrates a graph of voltage versus time for a conventional FCL device during a fault state.

FIG. 17 illustrates a graph of voltage versus time for a FCL device incorporating a multifilamentary superconducting article according to an embodiment.

The use of the same reference symbols in different drawings indicates similar or identical items.

### DETAILED DESCRIPTION

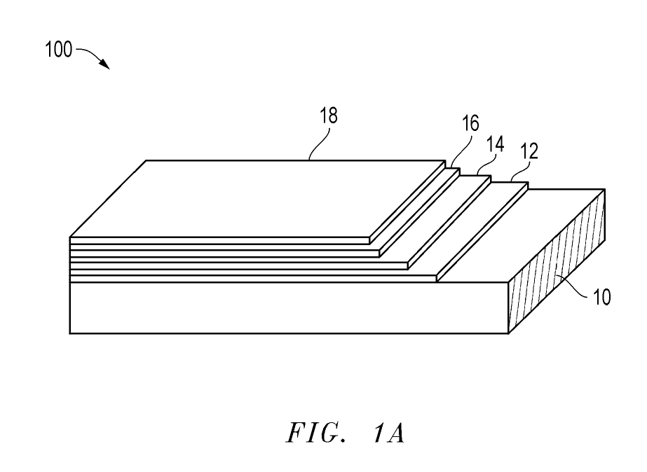

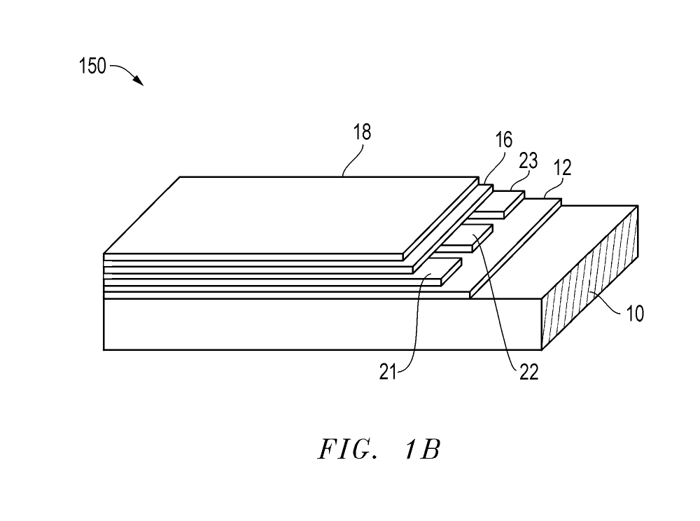

Turning to FIG. 1, the generalized layered structure of a superconducting article 100 according to an embodiment of the present invention is depicted. The superconducting article includes a substrate 10, a buffer layer 12 overlying the substrate 10, a superconducting layer 14, followed by a capping layer 16, typically a noble metal, and a stabilizer layer 18, typically a non-noble metal such as copper. The buffer layer 12 may consist of several distinct films. The stabilizer layer 18 may extend around the periphery of the superconducting article 100, thereby encasing it.

The substrate 10 is generally metal-based, and typically, an alloy of at least two metallic elements. Particularly suitable substrate materials include nickel-based metal alloys such as the known Hastelloy® or Inconel® group of alloys. These alloys tend to have desirable creep, chemical and mechanical properties, including coefficient of expansion, tensile strength, yield strength, and elongation. These metals are generally commercially available in the form of spooled tapes, particularly suitable for superconducting tape fabrication, which typically will utilize reel-to-reel tape handling.

The substrate 10 is typically in a tape-like configuration, having a high dimension ratio. As used herein, the term ‘dimension ratio’ is used to denote the ratio of the length of the substrate or tape to the next longest dimension, the width of the substrate or tape. For example, the width of the tape is generally on the order of about 0.1 to about 10 cm, and the length of the tape is typically at least about 0.1 m, most typically greater than about 5 m. Indeed, superconducting tapes that include substrate 10 may have a length on the order of 100 m or above. Accordingly, the substrate may have a dimension ratio which is fairly high, on the order of not less than 10, not less than about 10², or even not less than about 10³. Certain embodiments are longer, having a dimension ratio of 10⁴ and higher.

In one embodiment, the substrate is treated so as to have desirable surface properties for subsequent deposition of the constituent layers of the superconducting tape. For example, the surface may be polished to a desired flatness and surface roughness. Additionally, the substrate may be treated to be biaxially textured as is understood in the art, such as by the known RABiTS (roll assisted biaxially textured substrate) technique, although embodiments herein typically utilize a non-textured, polycrystalline substrate, such as commercially available nickel-based tapes noted above.

Turning to the buffer layer 12, the buffer layer may be a single layer, or more commonly, be made up of several films. Most typically, the buffer layer includes a biaxially textured film, having a crystalline texture that is generally aligned along crystal axes both in-plane and out-of-plane of the film. Such biaxial texturing may be accomplished by IBAD. As is understood in the art, IBAD is acronym that stands for ion beam assisted deposition, a technique that may be advantageously utilized to form a suitably textured buffer layer for subsequent formation of a superconducting layer having desirable crystallographic orientation for superior superconducting properties. Magnesium oxide is a typical material of choice for the IBAD film, and may be on the order of about 1 to about 500 nanometers, such as about 5 to about 50 nanometers. Generally, the IBAD film has a rock-salt like crystal structure, as defined and described in U.S. Pat. No. 6,190,752, incorporated herein by reference.

The buffer layer may include additional films, such as a barrier film provided to directly contact and be placed in between an IBAD film and the substrate. In this regard, the barrier film may advantageously be formed of an oxide, such as yttria, and functions to isolate the substrate from the IBAD film. A barrier film may also be formed of non-oxides such as silicon nitride. Suitable techniques for deposition of a barrier film include chemical vapor deposition and physical vapor deposition including sputtering. Typical thicknesses of the barrier film may be within a range of about 1 to about 200 nanometers. Still further, the buffer layer may also include an epitaxially grown film(s), formed over the IBAD film. In this context, the epitaxially grown film is effective to increase the thickness of the IBAD film, and may desirably be made principally of the same material utilized for the IBAD layer such as MgO or other compatible materials.

In embodiments utilizing an MgO-based IBAD film and/or epitaxial film, a lattice mismatch between the MgO material and the material of the superconducting layer exists. Accordingly, the buffer layer may further include another buffer film, this one in particular implemented to reduce a mismatch in lattice constants between the superconducting layer and the underlying IBAD film and/or epitaxial film. This buffer film may be formed of materials such as YSZ (yttria-stabilized zirconia) strontium ruthenate, lanthanum manganate, and generally, perovskite-structured ceramic materials. The buffer film may be deposited by various physical vapor deposition techniques.

While the foregoing has principally focused on implementation of a biaxially textured film in the buffer stack (layer) by a texturing process such as IBAD, alternatively, the substrate surface itself may be biaxially textured. In this case, the buffer layer is generally epitaxially grown on the textured substrate so as to preserve biaxial texturing in the buffer layer. One process for forming a biaxially textured substrate is the process known in the art as RABiTS (roll assisted biaxially textured substrates), generally understood in the art.

The superconducting layer 14 is generally in the form of a high-temperature superconductor (HTS) layer. HTS materials are typically chosen from any of the high-temperature superconducting materials that exhibit superconducting properties above the temperature of liquid nitrogen, 77K. Such materials may include, for example, YBa₂Cu₃O₇₋ₓ, Bi₂Sr₂CaCu₂O_{z}, Bi₂Sr₂Ca₂Cu₃O_{10+y}, Tl₂Ba₂Ca₂Cu₃O_{10+y}, and HgBa₂Ca₂Cu₃O_{8+y}. One class of materials includes REBa₂Cu₃O₇₋ₓ, wherein RE is a rare earth or combination of rare earth elements. Of the foregoing, YBa₂Cu₃O₇₋ₓ, also generally referred to as YBCO, may be advantageously utilized. YBCO may be used with or without the addition of dopants, such as rare earth materials, for example samarium. The superconducting layer 14 may be formed by any one of various techniques, including thick and thin film forming techniques. Preferably, a thin film physical vapor deposition technique such as pulsed laser deposition (PLD) can be used for a high deposition rates, or a chemical vapor deposition technique can be used for lower cost and larger surface area treatment. Typically, the superconducting layer has a thickness on the order of about 0.1 to about 30 microns, most typically about 0.5 to about 20 microns, such as about 1 to about 5 microns, in order to get desirable amperage ratings associated with the superconducting layer 14.

The superconducting article may also include a capping layer 16 and a stabilizer layer 18, which are generally implemented to provide a low resistance interface and for electrical stabilization to aid in prevention of superconductor burnout in practical use. More particularly, layers 16 and 18 aid in continued flow of electrical charges along the superconductor in cases where cooling fails or the critical current density is exceeded, and the superconducting layer moves from the superconducting state and becomes resistive. Typically, a noble metal is utilized for capping layer 16 to prevent unwanted interaction between the stabilizer layer(s) and the superconducting layer 14. Typical noble metals include gold, silver, platinum, and palladium. Silver is typically used due to its cost and general accessibility. The capping layer 16 is typically made to be thick enough to prevent unwanted diffusion of the components from the stabilizer layer 18 into the superconducting layer 14, but is made to be generally thin for cost reasons (raw material and processing costs). Various techniques may be used for deposition of the capping layer 16, including physical vapor deposition, such as DC magnetron sputtering.

The stabilizer layer 18 is generally incorporated to overlie the superconducting layer 14, and in particular, overlie and directly contact the capping layer 16 in the particular embodiment shown in FIG. 1. The stabilizer layer 18 functions as a protection/shunt layer to enhance stability against harsh environmental conditions and superconductivity quench. The layer is generally dense and thermally and electrically conductive, and functions to bypass electrical current in case of failure of the superconducting layer or if the critical current of the superconducting layer is exceeded. It may be formed by any one of various thick and thin film forming techniques, such as by laminating a pre-formed copper strip onto the superconducting tape, by using an intermediary bonding material such as a solder. Other techniques have focused on physical vapor deposition, typically evaporation or sputtering, as well as wet chemical processing such as electro-less plating, and electroplating. In this regard, the capping layer 16 may function as a seed layer for deposition of copper thereon. Notably, the capping layer 16 and the stabilizer layer 18 may be altered or not used, as described below in accordance with various embodiments.

Referring to FIG. 1B, a perspective view of an exemplary multifilamentary superconducting article 150 is illustrated. As illustrated, the multifilamentary superconducting article 150 can include a substrate 10 and an overlying buffer layer 12 as previously described. However, unlike the generalized superconductor article, the multifilamentary superconducting article 150 includes filaments 21, 22, and 23 (21-23) overlying the buffer layer. In general, filaments are elongated segments having a first end and a second end. According to one embodiment, the filaments 21-23 can include HTS material. Notably, the filaments 21-23 extend along the length of the article, and are discrete objects, having a distinct shape and size, laterally spaced apart from other filaments by a spacing distance and longitudinally spaced apart by a gap distance. As further illustrated, in one embodiment, such multifilamentary superconducting articles can include a capping layer 16 overlying the filaments 21-23 as well as a stabilizer layer 18 overlying the capping layer 16.

The formation of a multifilamentary superconducting article having discrete filaments facilitates the formation of a low AC loss superconducting article. The formation of discrete filaments along the length of a superconducting tape segment facilitates the reduction of magnetic interferences caused by the current flowing through the HTS layer. Accordingly, the formation of a superconducting article having filaments comprising the HTS material can facilitate the formation of an efficient and low AC loss superconducting article.

While FIG. 1B illustrates filaments 21-23 including only the HTS material, in another embodiment, the filaments can be made of materials within the constituent layers. As such, in one particular embodiment, the filaments 21-23 can be formed such that the HTS material and the buffer layer 12 are patterned to form filaments. In another particular embodiment, the filaments 21-23 can be formed such that the HTS material and the capping layer 16 are patterned to form the filaments. It will be appreciated that the filaments can be formed such that different layers are patterned to form filaments, including the stabilizer layer 18, the capping layer 16, the HTS layer 14, and the buffer layer.

Referring to FIG. 2, a top view of a portion of a multifilamentary superconducting article is illustrated. The article includes a base layer 201, which can include a substrate and overlying buffer layer as described herein. The multifilamentary superconducting article can further include filaments 203, 204, 205, 206, 207, 208, 209, and 210 (203-210) overlying portions of the base layer 201. The filaments can include the HTS material, as well as material from the buffer layer, capping layer, and stabilizing layer depending upon the embodiment.

As illustrated, the filaments 203-210 extend along the length of the multifilamentary superconducting article. Generally, the filaments 203-210 have a continuous length 217 of at least about 100 microns. In another embodiment, the filaments 203-210 can have a greater length, such as at least about 200 microns, or at least about 400 microns or even at least about 1000 microns. In one particular embodiment, the filaments 203-210 have a continuous length that extends along essentially the entire length of the tape segment. As previously described, such lengths can be far greater than micron size, since the multifilamentary superconducting tape segment can have lengths of at least about 5 m, and more typically on the order of at least about 10 m or even at least about 100 m. In one particular embodiment, the multifilamentary superconducting articles herein have a length within a range between about 1 m and about 1 km, such as within a range between about 5 m and about 100 m.

The filaments 203-210 can be laterally spaced apart by a spacing distance illustrated by the arrow 213. Generally, the spacing distance 213 separating adjacent filaments is not greater than about 1 mm. In other embodiments, the space 213 can be less, such as not greater than approximately 0.5 mm, not greater than about 0.25 mm or even not greater than about 0.1 mm. In one particular embodiment, the spacing distance 213 separating adjacent filaments is within a range between about 0.05 mm and about 1 mm, and more particularly within a range between about 0.1 mm and about 0.5 mm.

According to one embodiment, the filaments 203-210 can be longitudinally separated by gaps, illustrated as arrow 215, extending along the length of the tape segment. Generally, such gaps have a length that is less than the length of the filaments 203-210. According one embodiment, the gap is not greater than about 3 mm, such as not greater than about 1 mm, and in particular instances can be less. For example, in one embodiment, the gap 215 is not greater than about 100 microns, 75 microns, 50 microns, or even not greater than about 20 microns. Still, in one particular embodiment, the gap is within a range between 100 microns and about 400 microns. In one particular embodiment, the filaments 203-210 can extend for essentially the entire length of the substrate tape, and accordingly no substantial gaps are present.

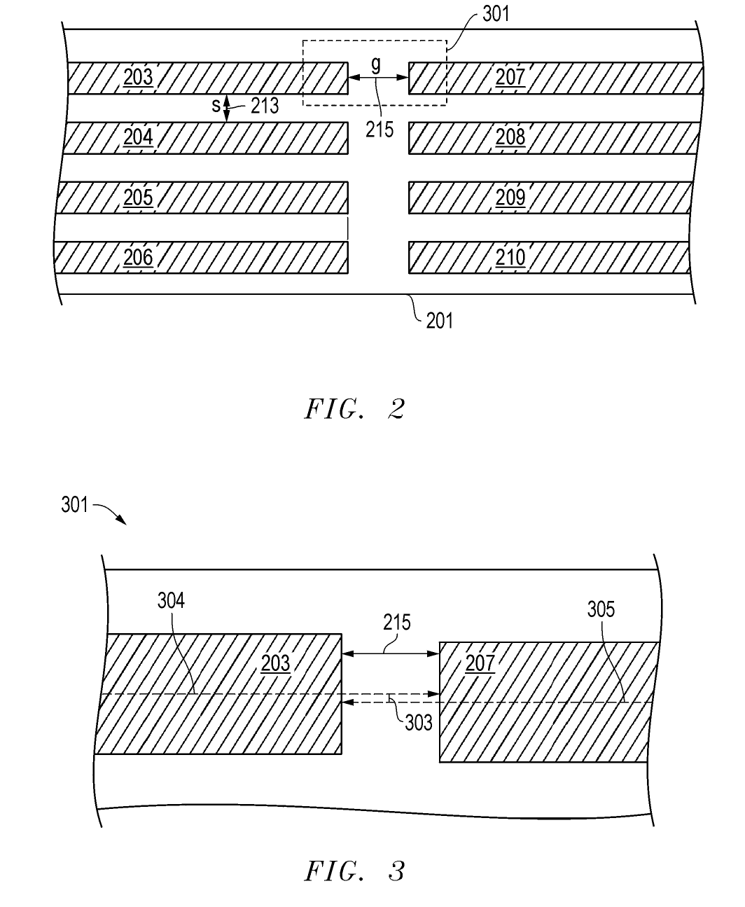

FIG. 3 illustrates a portion of the multifilamentary superconducting article as illustrated in FIG. 2. In particular, FIG. 3 illustrates a portion of the filament 203 and filament 207. As previously described, the filaments 203 and 207 can be separated by a gap 215. According to one embodiment, the filaments can have a lateral inter-filament misalignment, illustrated as a distance 303 between bisecting axes of corresponding filaments 203 and 207. The lateral inter-filament misalignment 303 is a measure of lateral displacement between two filaments longitudinally spaced apart from each other. As illustrated in FIG. 3, the lateral inter-filament misalignment 303 is a measurement orthogonal to the length of the filaments 203 and 207 based upon corresponding bisecting axes 304 and 305 of the filaments 203 and 207 respectively. According to one embodiment the lateral inter-filament misalignment 303 is not greater than about 100 microns. In another embodiment, the lateral inter-filament misalignment 303, is not greater than about 50 microns, or not greater than about 25 microns, or even not greater than about 10 microns. In one particular embodiment, the lateral inter-filament misalignment 303 is within a range between about 5 microns and about 100 microns, and more particularly within a range between about 10 microns to about 50 microns. The formation of a multifilamentary superconducting article having such lateral inter-filament misalignment 303 between discrete filaments facilitates the formation of precisely aligned filaments and a superconducting article having superior electrical characteristics, such as AC loss reduction.

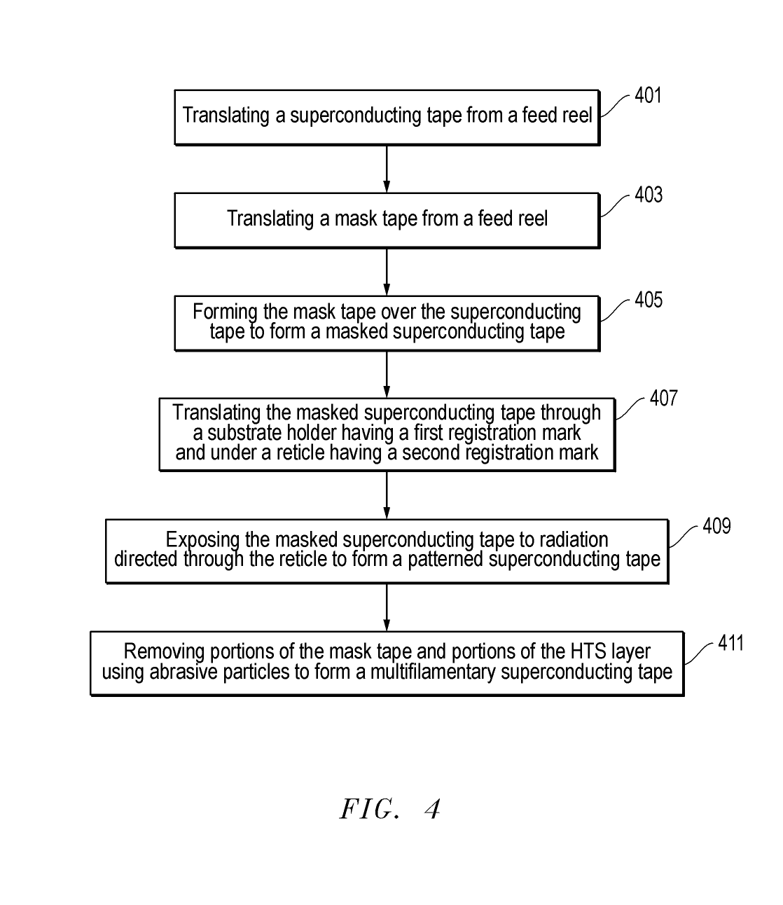

FIG. 4 illustrates a flow chart providing a process for forming a multifilamentary superconducting article according to one embodiment. In particular, FIG. 4 provides a method of forming a multifilamentary superconducting article using a reel-to-reel process, which facilitates the formation of long-length, multifilamentary superconducting articles. Accordingly, the process is initiated at step 401 by translating a superconducting tape from a feed reel. The superconducting tape can include a substrate, a buffer layer overlying the substrate, and a HTS layer overlying the buffer layer. Notably, the HTS layer at this stage is a generally conformal layer of material overlying the buffer layer, before discrete filaments are patterned from the HTS layer.

The process further includes translating a mask tape from a feed reel at step 403. In particular, the mask tape can be a long length of material in the form of a tape. According to one embodiment, the mask tape has dimensions similar to that of the superconducting tape. As such, in one embodiment, the mask tape has a dimension ratio that is at least about 10:1. In another embodiment, the mask tape has a dimension ratio of at least about 100:1 or even at least about 1000:1.

In particular reference to certain dimensions, in one embodiment, the mask tape has an average width that is generally the same as the superconducting tape segment. In one embodiment, the mask tape has an average width of not greater than about 10 cm. In another embodiment, the average width of the mask tape is not greater than about 5 cm, such as not greater than about 1 cm. In one particular embodiment, the mask tape has an average width within a range between about 1 mm and about 1 cm.

In another embodiment, the mask tape has an average thickness than is not greater than about 5 mm. Still, according to another embodiment, the mask tape has an average thickness that is not greater than about 2 mm, such as not greater than about 1 mm, or even not greater than about 0.5 mm. In certain embodiments, it is desirable that the mask tape be particularly thin, having an average thickness within a range between about 0.05 mm and about 0.25 mm.

According to one embodiment the mask tape can be a radiation-sensitive material. Including for example, a photolithography material or resist material used in the electronics industry. In one embodiment, the mask tape can include an organic material, such as a resin.

While translating the superconducting tape and the mask tape from a feed reel as provided in the steps 401 and 403 respectively, the process can continue at step 405 by forming the mask tape over the superconducting tape to form a masked superconducting tape. The process of forming the mask tape over the superconducting tape can include combining the two tapes such that the mask tape is overlying the HTS layer of the superconducting tape. According to one embodiment, the process of forming the mask tape over the superconducting tape includes laminating the mask tape over the superconducting tape by aligning the tapes laterally and pressing the two tapes together. In one particular embodiment, the process of laminating the mask tape over the superconducting tape includes translating the masked tape and superconducting tape together through a substrate holder and applying pressure to the tapes. For example, the mask tape and the superconducting tape can be translated through a substrate holder and pressure is applied to the tapes via a roller. In a more particular embodiment, the process of forming the mask tape over the superconducting tape can further include heating the mask tape and superconducting tape to facilitate suitable lamination. The heat can be applied locally to the tapes to facilitate lamination. In one embodiment, a combination of heat and pressure can be applied to complete lamination. In certain embodiments using heat, the temperature may be greater than approximately 50° F., such as greater than about 75° F. Typically, the temperature provided locally to the tapes during lamination is not greater than approximately 150° F.

During the lamination process, a moistening agent may be applied to the masked tape or superconducting tape or both tapes. The addition of a moistening agent be provided in the form of an aerosol or spray, which can be applied to the surfaces of the respective tapes to be joined in contact. Typically, the material applied to the superconducting tape and mask tape for purposes of moisture is a material that will not contaminate the constituent layers of the superconducting tape or mask tape. As such, in one embodiment, the moistening agent includes an aqueous-based solution. In a particular embodiment, the moistening agent can consist essentially of de-ionized water.

After combining the mask tape over the superconducting tape to form a masked superconducting tape as provided in step 405, the process can continue by translating the masked superconducting tape through a substrate holder having a first registration mark and under a reticle having a second registration mark as provided in step 407.

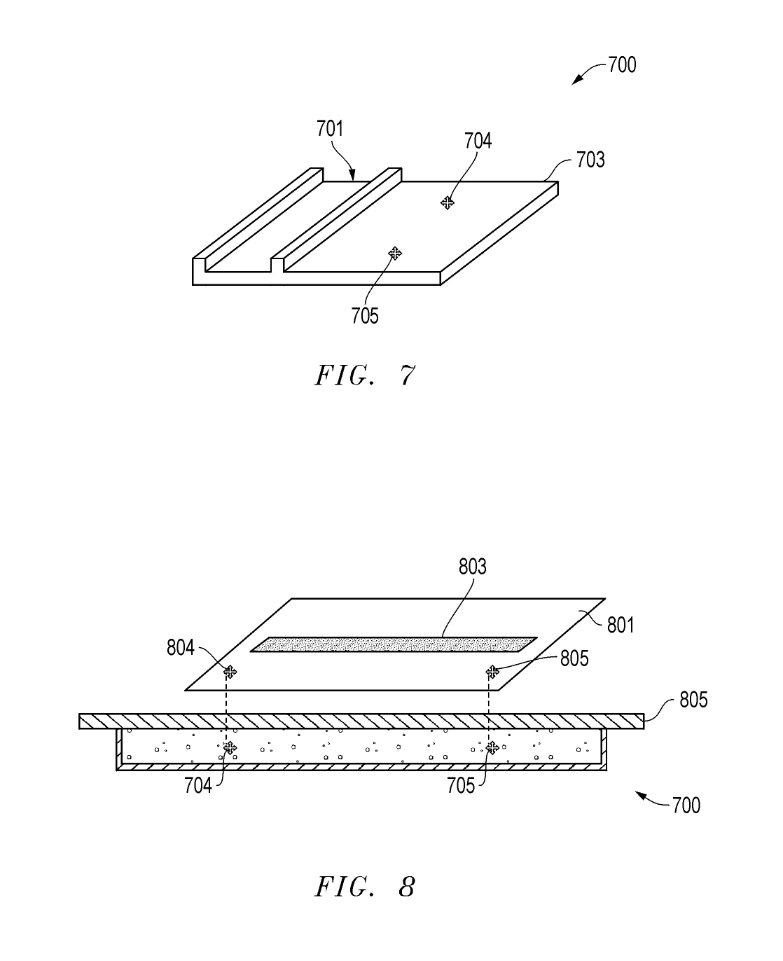

Referring briefly to FIGS. 7 and 8, these figures provide illustrations of articles (e.g., substrate holder and reticle) for use in aligning the masked superconducting tape during certain portions of the reel-to-reel process, according to embodiments herein. FIG. 7 includes a substrate holder according to one embodiment, while FIG. 8 illustrates a substrate holder and an overlying reticle according to one embodiment. In particular, FIG. 7 illustrates a perspective view of a substrate holder 700 having a channel 701 for receiving and aligning a long length tape and particularly the masked superconducting tape. In one particular embodiment, the substrate holder 700 can include a registration mark, or series of registration marks. As illustrated in FIG. 7, the substrate holder 700 includes registration marks 704 and 705 on the surface of a shelf 703 extending from the side of the channel 701. The registration mark 704 and 705 are suitable for aligning the substrate holder 700 with another object, and such marks can include suitable indicia such as holes, indentations, scratches, or the like.

FIG. 8 includes a perspective view of a substrate holder 700 underlying a reticle 801. As illustrated, the reticle 801 is overlying the substrate holder 700 and has registration marks 804 and 805 that are vertically aligned with the registration marks 704 and 705 of the substrate holder 700, facilitating alignment of the reticle 801 with respect to the substrate holder 700. The registration marks 804 and 805 of the reticle 801 can include marking indicia similar to those on the substrate holder 700.

Moreover, methods and devices use for aligning the registration marks can include mechanical, electrical, or optical methods. For example, in one particular embodiment, optical methods of alignment can include a laser and a sensor to align the registration marks. Mechanical methods can include registration marks that protrude from their respective surfaces and trip a switch.

After translating the masked superconducting tape through the substrate holder and under the reticle as provided in step 407, the process continues at step 409 by exposing the masked superconducting tape to radiation directed through the reticle to form a patterned superconducting tape. According to a particular embodiment, radiation can be directed through a pattern within the reticle such that portions of the masked superconducting tape are exposed to the radiation and other portions of the masked superconducting tape are not exposed to the radiation. Such a process facilitates changing the hardness of the masked tape portions exposed to the radiation, such as making them softer as compared to portions not exposed to the radiation.

Generally, the radiation directed through the reticle is of a particular wavelength. Suitable wavelengths generally include wavelengths of radiation less than approximately 500 nanometers. In one embodiment, the radiation has a shorter wavelength, such that it is typically referred to as an ultraviolet or deep ultraviolet wavelength, including those wavelengths less than approximately 400 nanometers, or even less than approximately 350 nanometers.

Referring again briefly to FIG. 8 to further illustrate the process of exposing portions of the tape to radiation, the reticle 801 includes a patterned portion 803, which when radiation is directed through, projects a particular pattern on the surface of the superconducting tape 805, thereby patterning the mask tape. Generally, the patterned portion 803 includes a pattern that facilitates the formation of the superconducting tape having discrete filaments. That is, in one embodiment, the patterned portion 803 comprises a pattern that is similar to, if not the same as, the final pattern of filaments formed on the multifilamentary superconducting tape. The combination of the reticle 801 overlying the substrate holder 700 facilitates a continuous reel-to-reel process, and more particularly the formation of filaments extending along a majority of the length of the superconducting tape segment. In one particular embodiment, the combination of the substrate holder 700 and the reticle 801 facilitates the formation of a multifilamentary superconducting tape that has filaments extending along the entire length of the superconducting tape segment without gaps.

Returning to the process provided in FIG. 4, after forming the patterned superconducting tape in step 409, the process continues at step 411 by removing portions of the mask tape and portions of the HTS layer using abrasive particles to form a multifilamentary superconducting tape. According to one embodiment, such a process includes using abrasive particles, and more particularly includes blasting the surface of the patterned superconducting tape with abrasive particles accelerated at high speeds using high pressure, wherein portions of the mask tape exposed to the radiation have become softer and are removed along with portions of the underlying HTS layer as opposed to portions of the mask tape which are harder and repel the abrasive particles. Such a process can be completed using a reel-to-reel process, wherein the patterned superconducting tape is distributed from a feed reel through a blasting zone wherein abrasive particles under high pressure are directed at the surface of the patterned superconducting tape to remove portions of the mask tape and portions of the underlying HTS layer. After translating the tape through the blasting zone, the formed multifilamentary superconducting tape can be gathered on a take-up spool.

The abrasive particles can include an inorganic material, such as an oxide, carbide, nitride, boride, or any combination thereof. In one particular embodiment, suitable abrasive particles can include silica, alumina, silicon carbide, diamond, cubic boron nitride, or any combination thereof. In one particular embodiment the abrasive particles include silica or alumina.

The average particle size is suitable to facilitate patterning of filaments using a reel-to-reel process. Accordingly, in one embodiment, the abrasive particles have an average particle size of not greater than 100 microns. In another embodiment, the abrasive particles are smaller, such as not greater than about 75 microns, not greater than about 50 microns, not greater than about 25 microns, or even not greater than about 10 microns. According to a particular embodiment, the particle size of the abrasive particles is within a range between about 1 micron and about 75 microns, and more particularly within a range between about 5 microns and about 50 microns.

After removing portions of the mask tape and portions of the HTS tape using abrasive particles to form a multifilamentary superconducting tape having discrete filaments, portions of the mask tape can still overlie portions of the tape that were not removed by the abrasive particles. Accordingly, the process can further include removing those portions of the mask tape by exposing them to a cleaning agent. Suitable cleaning agents can include inorganic or organic material. In one particular embodiment, the cleaning agent is an aqueous-based solution. In a more particular embodiment, the cleaning agent can include de-ionized water. In one particular embodiment, the process of cleaning the multifilamentary superconducting tape can include translating the multifilamentary superconducting tape through a bath on a reel-to-reel process. Such a bath can include exposing the multifilamentary superconducting tape to heat to remove those portions of the mask tape overlying the mask tape overlying the HTS filaments. In another embodiment, the process of cleaning the multifilamentary superconducting tape can further include spraying the top surface of the multifilamentary superconducting tape with a cleaning agent and may also include agitation of the multifilamentary superconducting tape, such as by ultra-sonication.

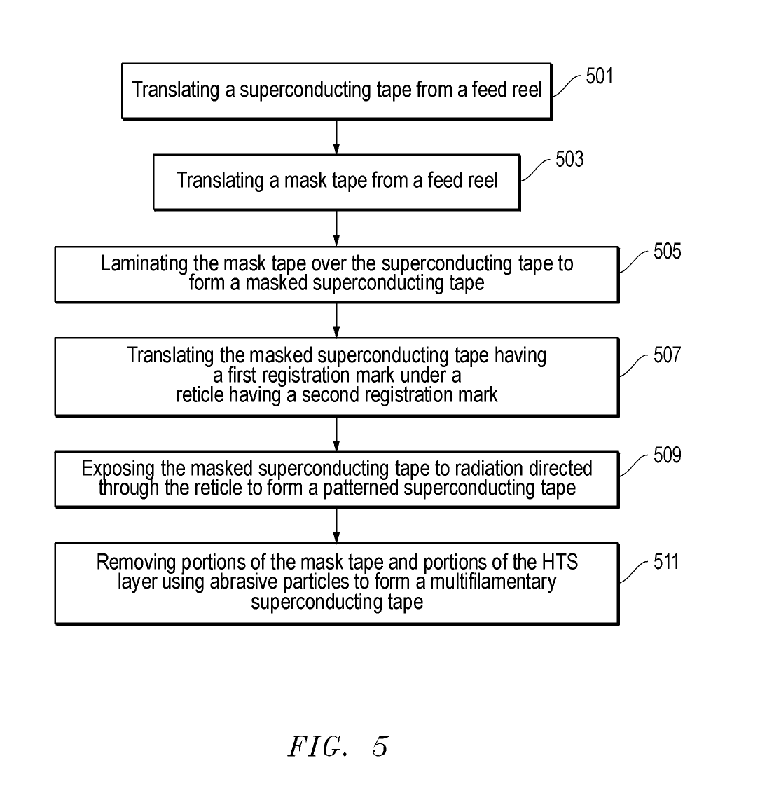

FIG. 5 includes a process for forming a multifilamentary superconducting tape according to one embodiment. Certain portions of the process illustrated in FIG. 5 are similar to those processes previously described in accordance with the process of FIG. 4. In particular, steps 501, 503, and 505 are substantially the same as the processes described in FIG. 4. Step 507 of the process includes translating the masked superconducting tape having a first registration mark under a reticle having a second registration mark. In this particular embodiment, the mask superconducting tape includes the registration mark, and accordingly such a process may not make use of a substrate holder.

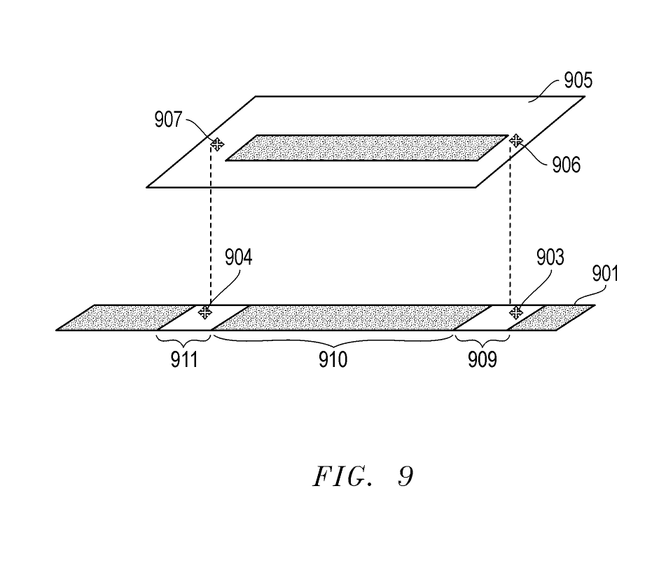

Referring briefly to FIG. 9, a perspective view of a masked superconducting tape having registration marks and a reticle overlying the masked superconducting tape having corresponding registration marks is provided. As illustrated, the masked superconducting tape 901 includes registration marks 903 and 904 spaced apart along the length of the tape. Additionally, the reticle 905 includes registration marks 906 and 907 corresponding to and aligning with registration marks 903 and 904 respectively. Alignment of the registration marks 903 and 904 with the registration marks 906 and 907 facilitate alignment of the masked superconducting tape 901 with the reticle 905 and therein facilitates efficient and effective patterning of the mask tape. Moreover, the types of registration marks 903 and 904 can be the same as those previously described in accordance with FIGS. 7 and 8.

As further illustrated in FIG. 9, the masked superconducting tape can include portions 909 and 911 along the length of the mask superconducting tape 901 for including the registration marks 903 and 904. In one embodiment, portions 909 and 911 can include segments of the masked superconducting tape wherein the mask tape does not overlie the superconducting tape segment. In another embodiment, portions 909 and 911 include segments of the masked superconducting tape wherein there is no existing HTS layer under the mask tape such that the portions 909 and 911 correspond to gaps between the filaments in the finally formed multifilamentary superconducting tape. The portions 909 and 911 can facilitate the alignment of the masked superconducting tape 901 with the reticle via registration marks 903 and 904 and the formation of gaps between filaments which are formed in the intermediate region 910 in the finally formed multifilamentary superconducting tape.

Referring still to FIG. 9, the process of translating the masked superconducting tape 901 having registration marks 903 and 904 can be completed in a reel-to-reel process. In one particular embodiment, the reel-to-reel process can include a stepping process, wherein the reel is translated for a distance and stopped to align the registration marks 903 and 904 of the masked superconducting tape 901 with the registration marks 906 and 907 of the reticle 905 and then expose the intermediate portion 910 of the masked superconducting tape 901 to radiation. After one portion is exposed to the radiation, the tape can be translated for a distance again and stopped and different registration marks along the length of the masked superconducting tape 901 can be aligned again with the registration marks 906 and 907 of the reticle 905 and the exposure process can be repeated. The methods of alignment of the registration marks 903 and 904 on the masked superconducting tape 901 with the registration marks 906 and 907 can be the same as described herein in accordance with FIGS. 7 and 8.

Referring again to FIG. 5, after translating the masked superconducting tape having the registration mark under the reticle, the process continues in the same manner as described in accordance with FIG. 4. In particular, the process continues by exposing portions of the masked superconducting tape to radiation directed through the reticle to form a patterned superconducting tape as provided in the step 509, and further removing portions of the mask tape and portions of the HTS layer underlying portions of the mask tape using abrasive particles to form a multifilamentary superconducting tape as provided in step 511.

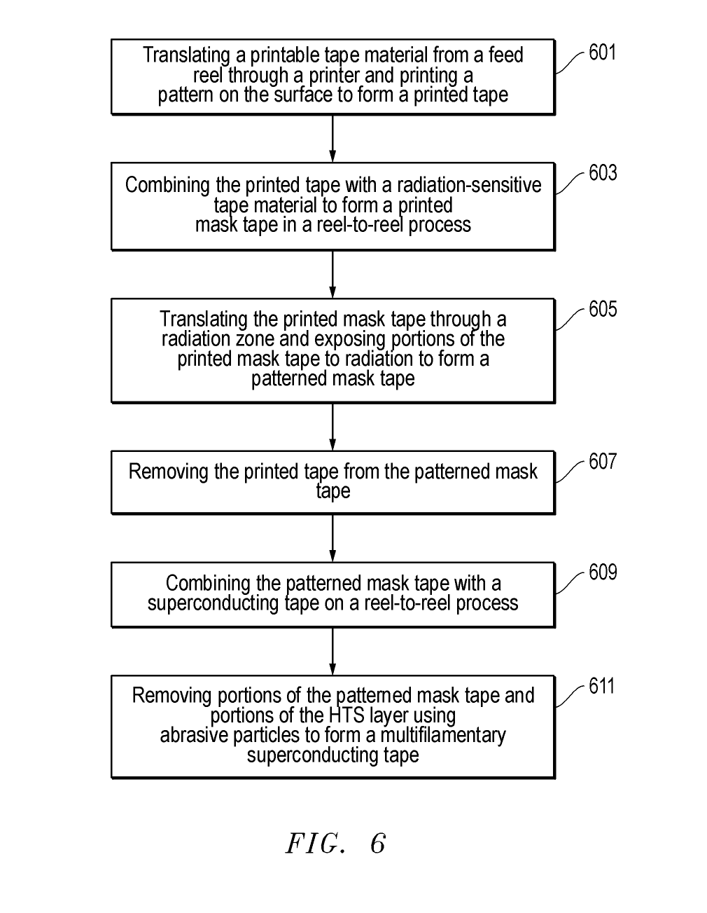

FIG. 6 includes a flow chart illustrating a method of forming a multifilamentary superconducting article on a reel-to-reel process according to one embodiment. The process is initiated at step 601 by translating a printable tape material from a feed reel through a printer and printing a pattern on the surface to form a printed tape. According to one embodiment, the printable tape material can include a long-length tape material that is transparent or is substantially transparent to particular wavelengths of radiation. In one particular embodiment, the printable tape material can include organic materials. In another particular embodiment, the printable tape material can include organic materials such as polyester and polyethylene, or combinations thereof. In more particular embodiment, the printable tape material comprises a biaxially-oriented polyethylene terephthalate polyester film, also referred to as Mylar®.

As the printable tape material can be translated in a reel-to-reel process, the printable tape material generally has those dimensions similar to the superconducting tape material. According to one embodiment, the printable tape material has a dimension ratio of not less than about 10:1. In another embodiment, the printable tape material has a dimension ratio of not less than 100:1 or even not less than about 1000:1.

As provided above, the printable tape material can be substantially transparent to certain wavelengths of radiation. In one particular embodiment, the printable tape material is transparent to ultraviolet radiation, that is radiation having a wavelength less than approximately 500 nm, and more particularly less than approximately 400 nm. Moreover, the printable tape material has an average thickness that is suitable for allowing radiation to transmit through its thickness. In one particular embodiment the printable tape material has an average thickness that is not greater than approximately 5 mm. In other embodiments, the printable tape material is thinner, such that the average thickness is not greater than approximately 3 mm, or even not greater than approximately 1 mm. In one particular embodiment, the printable tape material has an average thickness that is within a range between about 0.05 mm and about 0.25 mm.

In reference to the process of printing a pattern on the surface of the printable tape material, generally the printable tape material is translated in a reel-to-reel process through the printer to form the printed tape. The pattern on the surface can be representative of the filaments to be formed on the final multifilamentary superconducting tape. That is, the pattern can include images of filaments having discrete images resembling filaments spaced apart from each other and including gaps between groups of filaments.

After forming the printed tape in step 601 the process continues at step 603 by combining the printed tape with a radiation-sensitive tape material to form a printed mask tape in a reel-to-reel process. The printed tape can be unwound from a first feed reel and the radiation-sensitive material can be unwound from a second reel and the two tapes can be combined and gathered on a single take-up reel. Generally, the radiation-sensitive tape material used in this embodiment is the same material used in embodiments described in FIGS. 4 and 5. That is, the radiation-sensitive tape material can generally include an organic material, such as a resin or the like. Moreover, the radiation-sensitive tape material includes a material that becomes soft when exposed to a particular wavelength of radiation.

The process of combining the printed tape with the radiation-sensitive tape material can include a lamination process. The lamination process can include a process similar to that described previously in accordance with FIG. 4. As such, the lamination process can include rolling the respective tapes together, which may further include the application of pressure, heat, or moisture, and any combination thereof.

In one particular embodiment, the printed tape can be combined with the radiation-sensitive tape material such that the pattern on the surface of the printed tape is not in contact with a surface of the radiation-sensitive tape material. Alternatively, in another embodiment, the printed tape is combined with the radiation-sensitive tape material such that the pattern on the surface of the printed tape is in contact with a major surface of the radiation-sensitive tape material.

After forming the printed mask tape at step 603, the process continues at step 605 by translating the printed mask tape through a radiation zone and exposing portions of the printed mask tape to radiation to form a patterned mask tape. Accordingly, the pattern on the printed mask tape, particularly darker portions of the pattern, can block the radiation while unprinted portions can allow the radiation through to develop the underlying radiation-sensitive tape material. As previously described, portions of the printed masked tape exposed to the radiation, particularly those portions of the printed mask tape comprising the radiation-sensitive tape material can become softer due to the exposure to the radiation.

After forming the patterned masked tape at step 605, the process continues at step 607 by removing the printed tape from the patterned masked tape. In one particular embodiment, after exposing portions of the printed masked tape to radiation, the printed tape can be separated from the radiation-sensitive tape material. In one embodiment, removing the printed tape from the pattern masked tape can be completed using an interleaf stripper.

After removing the printed tape from the patterned masked tape at 607, the process can continue at step 609 which includes combining the patterned masked tape with a superconducting masked tape on a reel-to-reel process. Generally, the superconducting tape includes a substrate, a buffer layer overlying the substrate, and a conformal HTS layer overlying the buffer layer. In one embodiment, the superconducting tape can also include a capping layer or stabilizer layer, or both. Combining the patterned masked tape with the superconducting tape can include a lamination process as described herein.

After combining the patterned masked tape with the superconducting tape in step 609, the process can continue at step 611 by removing portions of the patterned masked tape and portions of the HTS layer using abrasive particles to form a multi-filamentary superconducting tape, as described previously in accordance with FIG. 4. As such, the process can include translating the combined patterned masked tape and superconducting tape through a blasting region wherein abrasive particles are directed at the surface of the patterned masked tape and superconducting tape under high pressure to remove portions of the patterned masked tape and HTS layer.

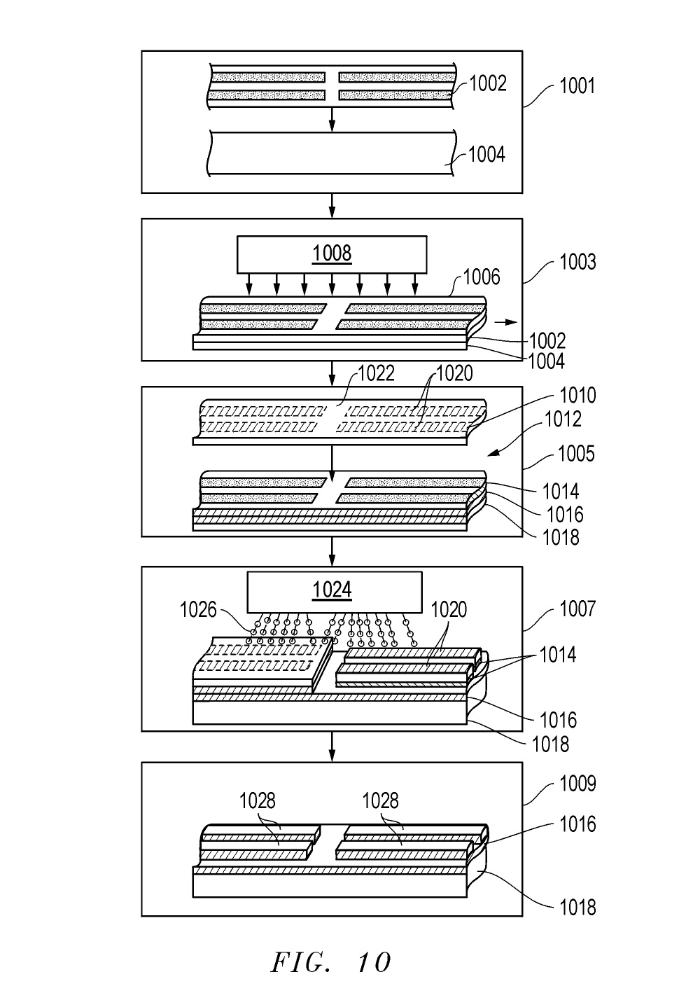

FIG. 10 includes a series of illustrations providing pictorial representations of a process of forming a multifilamentary superconducting article in a reel-to-reel process according to the process described in FIG. 6. As illustrated, the process can be initiated at step 1001 by combining the printed tape 1002 having a printed pattern on its surface with a radiation-sensitive tape material 1004. The printed tape 1002 includes a pattern on the surface resembling HTS filaments that extend along a length of the tape and are spaced apart laterally by a spacing distance, and further include gaps that extend longitudinally along the length of the tape.

After combining the printed tape 1002 with the radiation-sensitive tape material 1004 to form the printed masked tape, the process continues at step 1003 wherein the printed masked tape 1006 is translated through a radiation zone 1008, wherein radiation is direct at the surface of the printed masked tape 1006 to expose portions of the radiation-sensitive tape material 1004. As described herein, such a process facilitates softening of those portions of the radiation-sensitive tape material 1004 that are exposed to the radiation.

After exposing portions of the printed masked tape 1006 to radiation at step 1003 the process continues at step 1005 wherein the patterned masked tape 1010 is combined with a superconducting tape 1012. As described herein, after exposing the tape to radiation, the overlying printed tape 1002 can be removed, leaving behind the patterned masked tape 1010 (i.e., the radiation-sensitive tape material) including portions 1020 which can be harder in comparison to softer portions 1022. The superconducting tape 1012 can include a substrate 1018, a buffer layer 1016 overlying the substrate, and a HTS layer 1014 overlying the buffer layer. According to one embodiment, the superconducting tape 1012 further includes a capping layer overlying the HTS layer 1014. In another embodiment, the superconducting tape 1012 further includes a stabilizer layer overlying the HTS layer 1014.

After combining the patterned masked tape 1010 with the superconducting tape 1012 at step 1005, the process continues at step 1007 wherein portions of the patterned masked tape 1010 and HTS layer 1012 are removed using abrasive particles. The superconducting tape 1012 with the overlying patterned masked tape 1010 can be translated through a blasting zone 1024 which directs abrasive particles 1026 under pressure toward the surface of the patterned masked tape 1010. Such a process facilitates removal of certain portions of the patterned masked tape 1010 as well as the portions of the HTS layer 1014 underlying softer portions 1022 of the patterned masked tape 1010. Accordingly, after translating the tape through the blasting region 1024, portions of the HTS layer 1014 and portions 1020 of the pattern masked tape still remain and resemble filaments.

The process continues at step 1009, wherein after removing portions of the patterned masked tape 1010 to form filaments 1028 overlying the buffer layer 1016, portions 1020 of the patterned masked tape remaining can be removed. Accordingly, such a process for removing portions of the patterned masked tape 1020 overlying the filaments 1028 can include a rinse as described herein in accordance with FIG. 4. After this process, a capping layer and/or stabilizer layer can be provided over the filaments 1028. While, FIG. 10 illustrates the formation of a multifilamentary superconducting article having filaments comprising only the HTS layer, it will be appreciated that other multifilamentary superconducting articles can be formed by the same process and include filaments including portions of the buffer layer, capping layer, stabilizer layer, or any combination thereof.

As such, formation of a multifilamentary superconducting article according to embodiments herein facilitates the formation of a superconducting article having improved current capacity. As will be illustrated herein, the multifilamentary superconducting articles formed herein have a critical current retention ratio of at least about 0.6. In certain embodiments, this ratio is greater, such as at least about 0.65, at least about 0.70, or even at least about 0.75. In one particular embodiment, the critical current retention ratio is within a range between 0.60 and about 0.90.

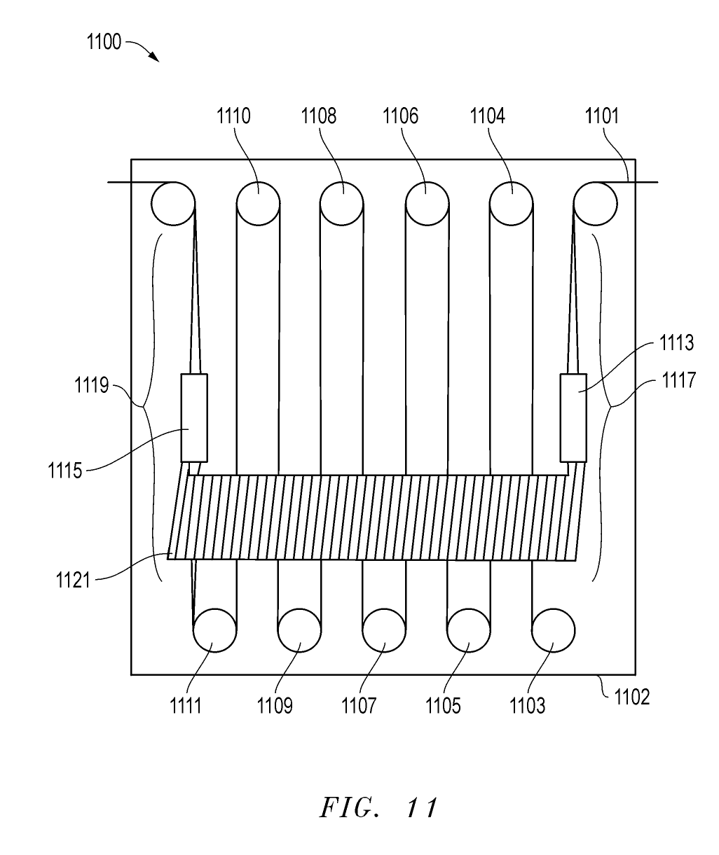

Referring to FIG. 11 a top view of a fault current limiter (FCL) device 1100 is illustrated. The FCL device 1100 includes a multifilamentary superconducting tape segment 1101 having filaments comprising HTS material extending along the length of the tape segment and formed according to one of the embodiments described herein. Generally, the superconducting tape segment 1101 has a length of not less than about 0.1 m, such as not less than about 5 m, or not less than about 10 m, or even not less than about 100 m. Typically, the superconducting tape segment 1101 has a length that is not greater than about 1 km.

In one embodiment, the multifilamentary superconducting tape segment 1101 is suspended above a base 1102 and wrapping around contacts 1103, 1104, 1105, 1106, 1107, 1108, 1109, 1110, 1111 (1103-1111) such that the path the multifilamentary superconducting tape segment 1101 is substantially non-inductive. Generally, the multifilamentary superconducting tape segment 1101 can be suspended between the contacts 1103-1111 to facilitate exposure to a cooling medium. Accordingly, in one embodiment, not less than about 50% of the total external surface area of the multifilamentary superconducting tape segment 1101 is exposed to the cooling medium. In another embodiment, not less than about 75%, such as not less than about 90%, or even not less than about 98% of the total external surface area of the superconducting tape is exposed to the cooling medium.

In the particular illustrated embodiment, the multifilamentary superconducting tape segment 1101 is suspended between contacts over the base 1102. According to a particular embodiment, the multifilamentary superconducting tape segment 1101 is suspended over the base 1102 on its side, such that planes tangential to the top and bottom surfaces of the tape segment are perpendicular or substantially perpendicular to the major plane of the base 1102. According to one embodiment, not less than about 75% of the total length of the multifilamentary superconducting tape segment 1101 is suspended above the base 1102. In another embodiment, not less than about 90% of the total length of the tape segment is suspended, still, in other embodiments, essentially the entire length of the multifilamentary superconducting tape segment 1101 is suspended above the base 11102.

The multifilamentary superconducting tape 1101 can be electrically coupled to a shunting circuit 1121. Accordingly, the FCL device can include a single or a plurality of shunting circuits spanning the entire distance of the meandering path. As illustrated in FIG. 11, the shunting circuit 1121 spans a number of contacts without making electrical contact. According to one embodiment, the shunting circuit 1121 can include at least one impedance element (i.e., resistors and/or inductors) and more typically, a plurality of impedance elements spanning the distance of the meandering path. In one embodiment, the plurality of impedance elements can be connected in series to each other. The number of impedance elements connected in series is generally greater than about 2, such as not less than about 5, or even not less than about 10 impedance elements.

Generally, the impedance elements are selected to have a particular impedance based upon the length of multifilamentary superconducting tape segment that the shunting circuit spans, such that each impedance element protects a certain length of the multifilamentary superconducting tape segment. In one embodiment, the shunting circuit includes impedance elements having an impedance of not less than about 0.1 milliOhms per meter of tape protected. Other embodiments utilize a greater impedance per length of tape protected, such that the impedance elements have a value of not less than about 1 milliOhms per meter of tape protected, or not less than about 5 milliOhms per meter of tape protected, or even not less than about 10 milliOhms per meter of tape protected, and even up to about 1.0 Ohm per meter of tape protected.

According to one particular embodiment, the multifilamentary superconducting tape segment 1102 includes rotation regions 1117 and 1119 where the multifilamentary superconducting tape segment 1101 is tilted or rotated. According to the illustrated embodiment, the rotation regions 1117 and 1119 are particularly localized along straight portions of the superconducting tape segment 401. Such rotation regions 1117 and 1119 facilitate coupling of the superconducting tape segment 401 to electrical contacts 1113 and 1115, which in turn couple the superconducting tape segment 1101 to a shunting circuit 1121. Notably, within the rotation regions 1117 and 1119 the multifilamentary superconducting tape segment 1101 is rotated such that at least a portion of the superconducting tape segment 401 is parallel to the base 1102 and lies flat against a contact surface of the electrical contacts 1113 and 1115. It will be appreciated that such FCL devices can include a plurality of multifilamentary superconducting articles that can be joined and operate in series, or alternatively operate in parallel configurations.

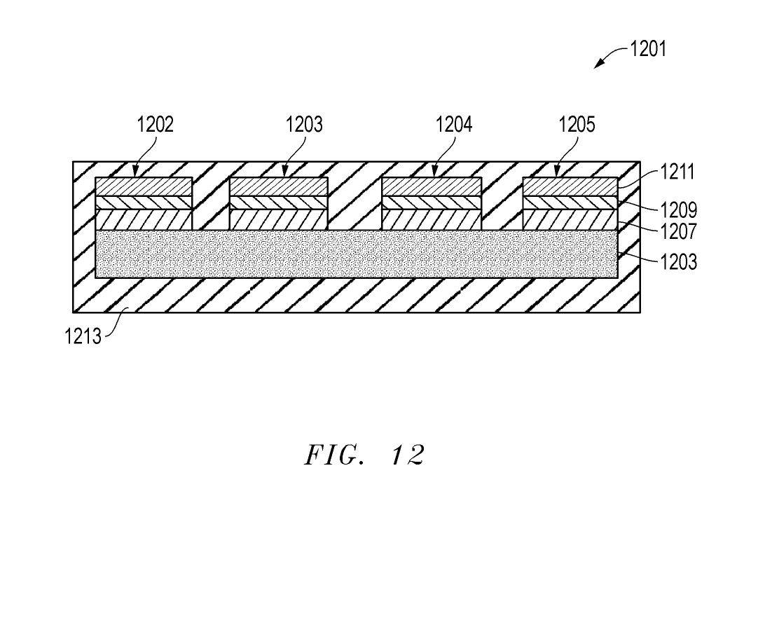

FIG. 12 includes a cross-sectional illustration of a portion of a multifilamentary superconducting tape segment 1201 for use in a FCL device. In particular, the multifilamentary superconducting tape segment 1201 includes a substrate 1203, and filaments 1202, 1203, 1204, and 1205 (1202-1205) overlying the substrate 1203. In one particular embodiment, the multifilamentary superconducting tape segment 1201 is formed such that particular layers are contained within the filaments 1202-1205 extending along the length of the tape segment. In one embodiment, the filaments 1202-1205 include a buffer layer 1207, a HTS layer 1209, and a capping layer 1211. In one embodiment, the multifilamentary superconducting tape segment 1201 can further include an optional stabilizer layer 1213 overlying all of the layers. Typically, such a multifilamentary superconducting tape segment 1201 may be difficult to form using conventional chemical etch processes, as different chemicals may have to be used to selectively etch each of the different layers. However, multifilamentary superconducting tape segments having this arrangement are easily formed using the processes described herein.

### EXAMPLES

Referring to Table 1 below, comparative data is provided that illustrates improved current retention capabilities of multifilamentary superconducting tape segments formed according to embodiments provided herein as compared to conventional multifilamentary superconducting tape segments formed using a chemical etch process. Samples 1-6 include samples formed via the processes described herein, including a masking, patterning, and abrasive removal technique. The Samples 1-5 are multifilamentary superconducting articles including filaments made of a HTS layer and a stabilizer material overlying an Inconel substrate and biaxially-textured buffer layer including MgO.

The Standard Samples 1-3 were formed using a standard chemical etching process including the use of 0.5 M citric acid. Standard Samples 1-3 include an Inconel substrate, an overlying conformal biaxially-textured buffer layer, and a HTS layer and stabilizer layer patterned to form filaments. In each of the samples provided in Table 1, the filaments were formed having a length of 33 cm a width of 600 microns and laterally separated by a space width of 400 microns. The gap length was 2.5 mm. The tape segments for all of the samples were 1 m long and 4 mm wide.

TABLE 1

| Sample | Ic Before | Ic After | Ic Retention Ratio |
|---|---|---|---|
| 1 | 145 | 91 | 0.63 |
| 2 | 145 | 88 | 0.60 |
| 3 | 145 | 95 | 0.66 |
| 4 | 145 | 94 | 0.65 |
| 5 | 145 | 93 | 0.64 |
| Std. 1 | 198 | 62 | 0.31 |
| Std. 2 | 183 | 28 | 0.15 |
| Std. 3 | 209 | 58 | 0.28 |

Table 1 provides critical current (Ic) values for the tape segments before the formation of filaments (Ic Before) and after the formation of the filaments (Ic After). The critical current (Ic) is a measure of the current carrying capabilities of an HTS tape, a significant characteristic of a superconducting article. More particularly, Table 1 provides data on the critical current retention ratio, which illustrates the percentage of lost current carrying capabilities attributed to forming the multifilamentary structure. As illustrated in Table 1, each of the Samples 1-5 formed according to embodiments described herein, demonstrated a greater critical current retention ratio as opposed to the Standard Samples (i.e., Std. 1-3) formed using a chemical etching process.

More particularly, each of the Samples 1-5 demonstrated a critical current retention ratio of at least 0.60 (i.e., 40%), which is about 30% greater than the best multifilament HTS samples formed via a chemical etching process (i.e., sample Std. 1) and thus are multifilament superconducting tapes capable of handling at least about 30% more current. All of the Samples 1-6 demonstrate a critical current retention ratio of at least 0.60, if not at least 0.65.

Moreover, each of the Standard Samples 1-5 demonstrated a greater absolute current carrying capability after the formation of the filaments. The greatest current value for the Standard Samples after formation of the filaments was 62 A, while the lowest current value for the Samples 1-5 was Sample 2 with a current of 88 A. Accordingly, Samples 1-5 demonstrate an improved absolute current capacity value after the forming process as compared to all of the Standard Samples.

Each of the Standard Samples were purposefully compared to Samples 1-5 because all of the samples demonstrated nearly the same degree of AC loss reduction. AC loss reduction is desirable in long-length conductors to minimize the power lost due to interfering magnetic fields generated from the movement of charges (i.e., a current). As such, Samples 1-5 demonstrate a greater current carrying capacity after patterning with the same degree of AC loss reduction, while the Standard Samples demonstrate a lesser current carrying capacity

Moreover, Samples 1-5 have a greater AC loss reduction than unpatterned superconducting articles. Referring to FIG. 13, a plot is provided illustrating the Power (W/m) versus Magnetic Field (B) for a control sample and Samples 1-5 provided above in Table 1. In particular, FIG. 13 illustrates the magnetic field generated for each of the samples over a range of power supplied to the samples. The control sample, plot 1301 is a non-patterned superconducting tape including the same materials within each of the layers. Samples 1-5, plot 1303, demonstrate a lower magnetic field generated through the range of increasing power, and thus greater AC loss reductions, since for any given level of power through the samples, a lower magnetic field is generated and thus AC losses are reduced.

The information provided above in Table 1 and FIG. 13 illustrate that the multifilamentary superconducting tapes formed according to embodiments herein superior to conventional multifilamentary superconducting articles and non-patterned superconducting articles. The multifilamentary superconducting tapes disclosed herein provide a greater critical current retention ratio and improved AC loss reduction over conventional superconducting tapes. While not wishing to be tied to any particular theory, the inventors note that the processes provided herein reduce the undercutting phenomena that occurs with a chemical etching process. Notably, undercutting is prevalent when using chemical etches to remove portions of layers, as the wet chemical etchant isotropically removes materials causing high lateral etching and damage to the HTS layer in the filaments.

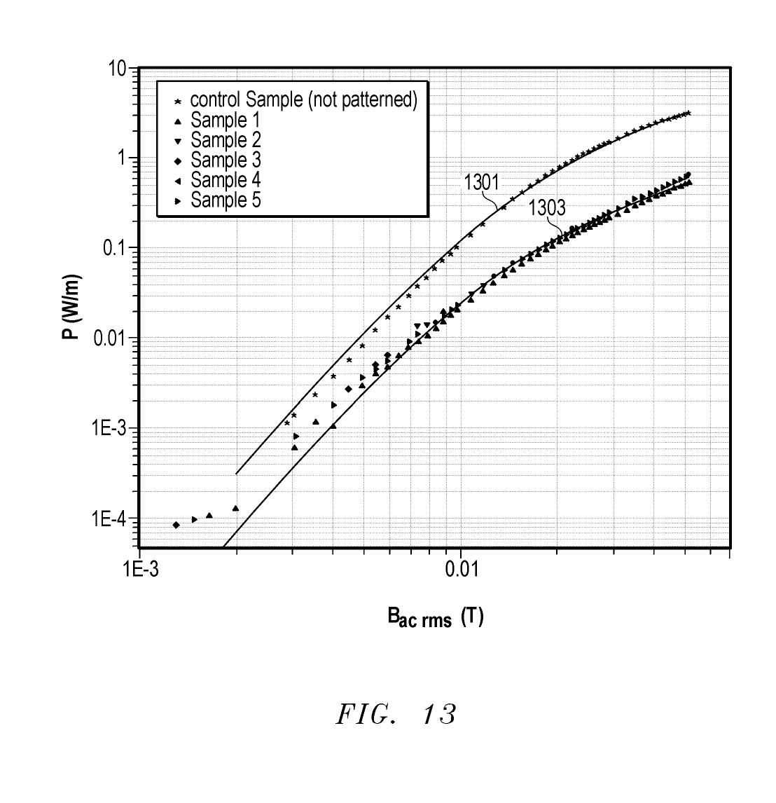

Additionally, the incorporation of the presently disclosed multifilamentary superconducting articles within FCL devices results in improved FCL characteristics. FIGS. 14-17 compare the function of conventional multifilamentary superconducting articles used in FCL devices to the multifilamentary superconducting articles formed according to processes described herein within FCL devices.

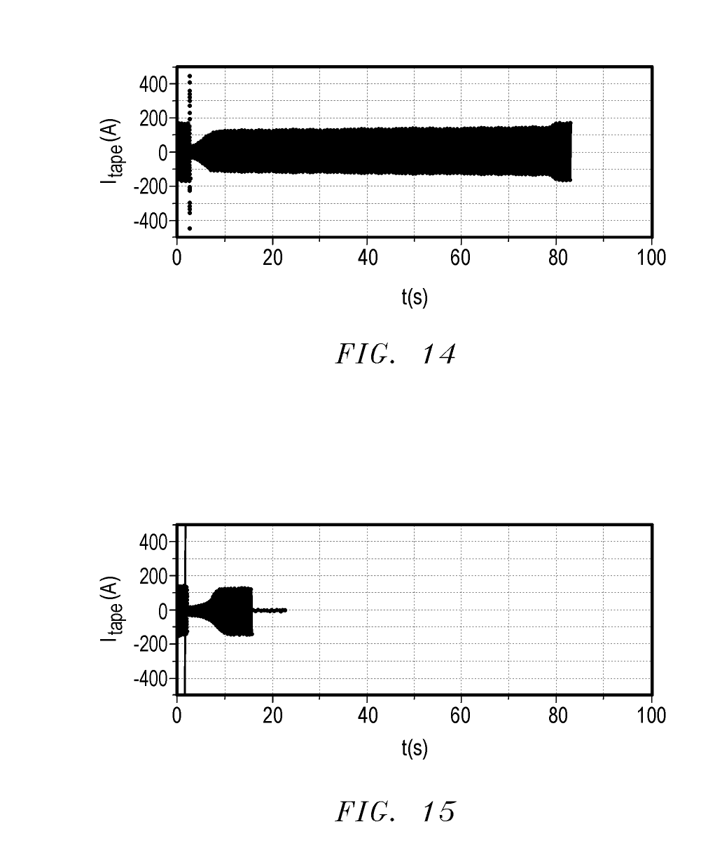

FIG. 14 includes a plot of current versus time during application of a fault current for a multifilamentary superconducting article formed according to conventional processes. By comparison, FIG. 15 includes a plot of current versus time during application of a fault current and subsequent recovery for a multifilamentary superconducting article formed according to processes disclosed herein. The conventional sample of FIG. 14 was an non-striated superconducting article having no filaments and including an Inconel substrate, a biaxially-textured buffer layer, a HTS material layer, and a capping material layer. The multifilamentary superconducting article also included a conformal stabilizer layer overlying the filaments. The unconventional sample of FIG. 15 was formed according to embodiments described herein, notably including a multifilamentary superconducting design and having a general structure of an Inconel substrate and filaments overlying the substrate, each filament including a biaxially textured buffer layer, HTS material, and a capping material. The filaments were 800 microns wide, 33 microns long, and were laterally spaced apart by 200 microns.

During tests conducted in a liquid nitrogen bath at 77 K, the conventional sample of FIG. 14, had a current of 168 A and the load current at fault was about 1600 A, while the unconventional sample of FIG. 15 had a current of 141 A and the load current at fault was 3540 A. All samples were connected to a 2.5 mOhm shunt coil. As illustrated by comparing FIGS. 14 and 15, the response time (i.e., the time to return to full recovery) of the conventional sample is about 80 seconds after application of the fault current, while the response time of the unconventional sample is approximately 10 seconds after application of the fault current. The unconventional sample demonstrates a superior response time when subject to a fault current of over twice as great a magnitude with comparable load currents.

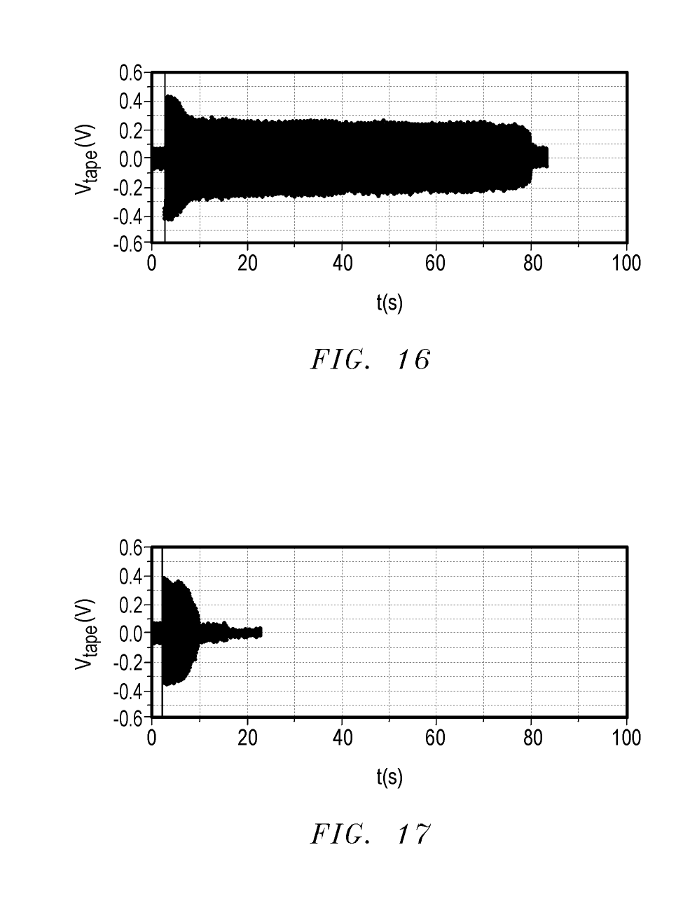

Referring to FIGS. 16 and 17, FIG. 16 includes a plot of voltage versus time during application of a fault current for a non-striated superconducting article (i.e., without filaments) formed according to conventional processes. FIG. 17 includes a plot of voltage versus time during application of a fault current for a multifilamentary superconducting article formed according to processes disclosed herein. The samples had the same structure as disclosed above with respect to the description of FIGS. 14 and 15. Again, in a comparison of FIGS. 16 and 17, the unconventional sample of FIG. 17 demonstrates a superior response time, even when subject to a fault current of twice as great a magnitude.

Accordingly, the multifilamentary superconducting articles, devices, and process disclosed herein demonstrate a departure from the state of the art. The embodiments herein describe a combination of elements including a process of forming multifilamentary superconducting articles using a reel-to-reel process, multiple tapes, masking processes, patterning processes, exposure techniques, and particular blasting techniques suitable for forming improved, long-length multifilamentary superconducting articles. Such processes are further enhanced by the use of particular devices, including a substrate holder, a reticle, combined with the features of registration marks. The combination of such processes and devices facilitate the formation of multifilamentary superconducting articles having precisely aligned filaments with low lateral inter-filamentary misalignment, improved AC loss reduction, and improved current carrying capacity. Moreover, the processes provided herein remove the need for multiple chemical etches and/or different chemical etches to form multifilamentary superconducting articles having filaments including different layers of material. Any one of the same forming processes disclosed herein can be used to form multifilamentary superconducting articles having filaments incorporating different layers of materials.

While certain references, for example U.S. 2007/0197395 and U.S. 2006/0040830, broadly recognize the possibility of patterning superconducting oxide films using abrasive milling or sandblasting, such references are particularly directed to chemical patterning techniques. And in fact, patterning an intermediate film before converting the intermediate film to an oxide superconductor. Moreover, such references, particularly U.S. 2007/0197395, explicitly disclose that the HTS material may harder to remove by abrasive techniques as compared to a softer chemical intermediate film, or may be damage after forming the HTS material, as it is generally a brittle oxide layer. Additionally, while general passing references are made to use of abrasives, none of these references discloses the combination of features including a reel-to-reel process, devices for facilitating the reel-to-reel operation, particular masking techniques, or the abrasive blasting technique disclosed herein. Much less, none of the references demonstrate the formation of long-length multifilamentary superconducting articles having improved critical current retention or AC loss reduction, not to mention improvement of response times when used in FCL articles.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

What is claimed is:

1. A superconducting article comprising:
a multifilamentary superconducting tape segment comprising:
a substrate tape;
a buffer layer overlying the substrate; and
filaments comprising a high temperature superconducting (HTS) material overlying the buffer layer and extending along a length of the substrate, laterally spaced apart from an adjacent filament by a space, and longitudinally spaced apart by a gap, wherein the filaments comprise a lateral inter-filament misalignment of not greater than about 100 microns.

2. The superconducting article of claim 1, wherein the lateral inter-filament misalignment is not greater than about 50 microns.

3. The superconducting article of claim 1, wherein the multifilament superconducting tape segment has a length of at least about 5 m.

4. The superconducting article of claim 1, wherein the HTS filaments have a continuous length of at least about 100 microns.

5. The superconducting article of claim 1, wherein the HTS filaments are separated by gaps extending along the length of the substrate, the gaps having a length of not greater than a length of the HTS filament.

6. The superconducting article of claim 5, wherein the gaps have a length of not greater than about 3 mm.

7. The superconducting article of claim 1, wherein the space is not greater than 1 mm.

8. The superconducting article of claim 1, wherein the buffer layer comprises a biaxially textured film having biaxially aligned crystals both in-plane and out-of plane of the film.

9. The superconducting article of claim 1, wherein the multifilamentary superconducting tape segment is a component of a fault current limiter (FCL) device comprising:
a shunting circuit electrically connected in parallel to the multifilamentary superconducting tape segment.

10. A superconducting article comprising:
a multifilamentary superconducting tape segment comprising:
a substrate tape;
a buffer layer overlying the substrate; and
filaments comprising a high temperature superconducting (HTS) material overlying the buffer layer and extending along a length of the substrate and laterally spaced apart from an adjacent filament by a space, wherein the multifilamentary superconducting tape segment comprises a critical current retention ratio is at least about 0.6.

11. The superconducting article of claim 10, wherein the critical current retention ratio is at least about 0.65.

12. A method of forming a multifilamentary superconducting tape comprising:
translating a superconducting tape on a reel-to-reel process, the superconducting tape comprising:
a substrate;
a buffer layer overlying the substrate; and
a HTS layer overlying the buffer layer;
forming a mask overlying the superconducting tape; and
removing portions of the mask and portions of the HTS layer using abrasive particles to form a multifilamentary superconducting tape having HTS filaments extending along a length of the superconducting tape and being laterally spaced apart from adjacent HTS filaments by spaces.

13. The method of claim 12, wherein forming the mask comprises:
translating a mask tape from a feed reel;
translating the superconducting tape from a feed reel; and
laminating the mask tape over the superconducting tape to form a masked superconducting tape.

14. The method of claim 13, further comprising:
translating the masked superconducting tape through a substrate holder having a first registration mark; and
exposing portions of the masked superconducting tape to radiation directed through a reticle having a second registration mark, wherein the second registration mark corresponds to and aligns with the first registration mark.

15. The method of claim 13, further comprising:
translating the masked superconducting tape having a first registration mark under a reticle having a second registration mark;
aligning the first registration mark and the second registration mark; and
exposing portions of the masked superconducting tape to radiation directed through the reticle to form a patterned superconducting tape.

16. The method of claim 12, wherein forming the mask comprises:
translating a printable tape material from a feed reel through a printer; and
printing a pattern on a surface of the printable tape material within the printer to form a printed tape.

17. The method of claim 16, wherein the printable tape material comprises polyester.

18. The method of claim 16, further comprising:
translating the printed tape from a first feed reel;
translating a radiation-sensitive tape material from a second feed reel;
combining the printed tape and the radiation-sensitive tape material to form a printed mask tape; and
translating the printed mask tape to a take-up spool.

19. The method of claim 18 further comprising:
translating the printed mask tape from a feed reel through a radiation zone and exposing portions of the printed mask tape to radiation to form a patterned radiation-sensitive mask tape;
removing the printed tape from the patterned radiation-sensitive mask tape; and
laminating the patterned radiation-sensitive mask tape over the superconducting tape segment.

20. The method of claim 19, further comprising
abrading the surface of the patterned radiation-sensitive mask tape by directing abrasive particles having an average particle size of not greater than about 75 microns under pressure at a major surface of the patterned radiation-sensitive mask tape to remove portions of the patterned radiation-sensitive mask tape and portions of the HTS layer to form a multifilamentary superconducting tape having HTS filaments extending along a length of the superconducting tape.
